(19) United States
(12) Patent Application Publication
(10) Pub. No.: US 2020/0335423 A1
(43) Pub. Date: Oct. 22, 2020

(54) SEMICONDUCTOR DEVICE

(71) Applicant: TOSHIBA MITSUBISHI-ELECTRIC INDUSTRIAL SYSTEMS CORPORATION, Chuo-ku (JP)

(72) Inventor: Mitsuo SUGIMOTO, Chuo-ku (JP)

(73) Assignee: TOSHIBA MITSUBISHI-ELECTRIC INDUSTRIAL SYSTEMS CORPORATION, Chuo-ku (JP)

(21) Appl. No.: 16/959,881

(22) PCT Filed: Nov. 27, 2018
(86) PCT No.: PCT/JP2018/043611

§ 371 Date: Jul. 2, 2020

(51) Int. Cl. H01L 23/467; H01L 21/48; H05K 7/20

(52) U.S. Cl. CPC H01L 23/467; H05K 7/20145; H01L 21/4882

(57) ABSTRACT

A box-shaped housing has a first surface including an air inlet and a second surface which is different from the first surface. A cooling fan is provided on the second surface and configured to discharge air from the second surface. A partition plate is configured to partition a space inside the housing into a first space in contact with the first surface and a second space in contact with the second surface. The partition plate includes at least one opening to allow the cooling air generated by the cooling fan to flow through the first space into the second space. At least one semiconductor unit is disposed in the first space and cooled by the cooling air. A reactor unit is disposed in the second space to face the at least one opening.

### TECHNICAL FIELD

The present invention relates to a semiconductor device.

### BACKGROUND ART

Japanese Patent Laying-Open No. 2016-19324 (PTL 1) discloses a semiconductor device provided with a semiconductor unit and a cooling unit configured to cool the semiconductor unit by forced air cooling. In PTL 1, a plurality-of semiconductor units are vertically arranged inside a box-shaped housing, and a cooling fan is disposed to discharge the cooling air from the top surface.

### CITATION LIST

### Patent Literature

PTL 1: Japanese Patent Laying-Open No. 2016-19324

### SUMMARY OF INVENTION

### Technical Problem

In the semiconductor device described in PTL 1, in addition to the semiconductor unit, a reactor is installed in the internal space of the housing. Similar to the semiconductor unit, the reactor is a heat-generating component, and thus, it is required to be cooled.

In the thermal design of a reactor, in order to reduce the calorific value of the reactor per unit volume, it is often to reduce the current density of the reactor by using a wire with a larger diameter. Further, in order to increase the heat dissipation area, it is often to increase the number of turns of the reactor. However, these measures may lead to an increase in the size and weight of the reactor as well as an increase in the cost.

The present invention has been made to solve the problems as mentioned above, and an object of the present invention is to provide a semiconductor device capable of improving the heat dissipation of a reactor without increasing the size and weight thereof.

### Solution to Problem

According to an aspect of the present invention, the semiconductor device includes a box-shaped housing having a first surface which is formed with an air inlet and a second surface which is different from the first surface, a cooling fan provided on the second surface and configured to discharge air from the second surface, and a partition plate configured to partition a space inside the housing into a first space in contact with the first surface and a second space in contact with the second surface. The partition plate is formed with at least one opening so as to allow the cooling air generated by the cooling fan to flow through the first space into the second space.

The semiconductor device further includes at least one semiconductor unit disposed in the first space and cooled by the cooling air, and a reactor unit disposed in the second space so as to face the at least one opening.

### Advantageous Effects of Invention

According to the present invention, it is possible to provide a semiconductor device capable of improving the heat dissipation of a reactor without increasing the size and weight thereof.

### BRIEF DESCRIPTION OF DRAWINGS

FIG. 1 is a circuit block diagram illustrating the configuration of an uninterruptible power supply system according to an embodiment of the present invention;

FIG. 2 is a circuit diagram illustrating the configuration of a converter and an inverter illustrated in FIG. 1;

FIG. 3 is a side cross-sectional view of the uninterruptible power supply system;

FIG. 4 is a cross-sectional view taken along line IV-IV of FIG. 3;

FIG. 5 is an outline view of a partition plate;

FIG. 6 is a side cross-sectional view of an uninterruptible power supply system according to a first modification of the present invention;

FIG. 7 is a side cross-sectional view of an uninterruptible power supply system according to a second modification of the present invention; and

FIG. 8 is a cross-sectional view taken along line VIII-VIII of FIG. 7.

### DESCRIPTION OF EMBODIMENTS

Hereinafter, embodiments of the present invention will be described in detail with reference to the drawings. In the following description, the same or corresponding portions in the drawings are denoted by the same reference numerals, and the description thereof will not be repeated.

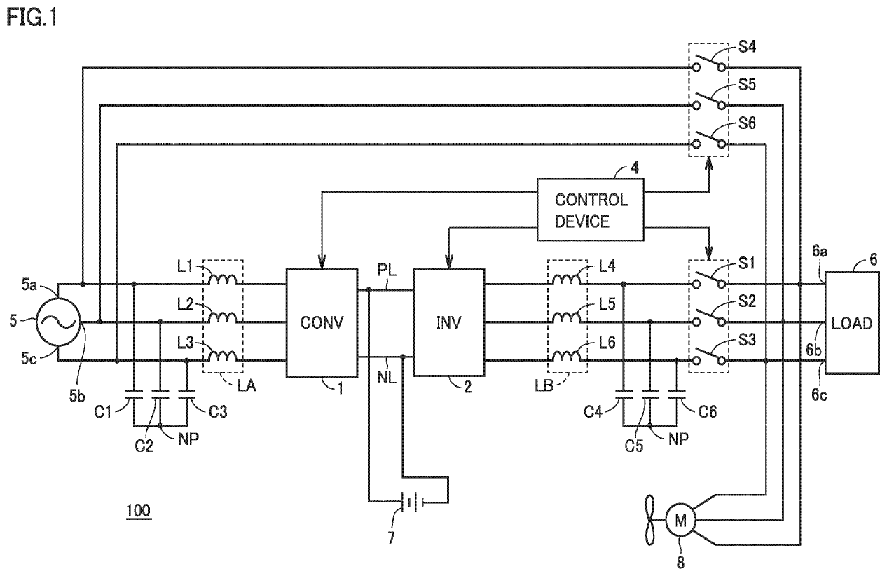

FIG. 1 is a circuit block diagram illustrating the configuration of an uninterruptible power supply system to which a semiconductor device according to an embodiment of the present invention is applicable. With reference to FIG. 1, an uninterruptible power supply system 100 includes AC input terminals 5a to 5c, capacitors C1 to C6, reactors L1 to L6, a converter 1, DC lines PL and NL, an inverter 2, AC output terminals 6a to 6c, and a controller 4. The uninterruptible power supply system 100 receives three-phase AC power of commercial frequency from a commercial AC power supply 5 and supplies the three-phase AC power of commercial frequency to a load 6.

The commercial AC power supply 5 is a three-phase three-wire system configured to output a three-phase AC voltage to the AC input terminals 5a to 5c. The load 6 is a three-phase three-wire load connected to the AC output terminals 6a to 6c.

One electrodes of the capacitors C1 to C3 are respectively connected to the AC input terminals 5a to 5c, and the other electrodes thereof are collectively connected to a node NP. One terminals of the reactors L1 to L3 are respectively connected to the AC input terminals 5a to 5c, and the other terminals are respectively connected to the input nodes of the converter 1.

The capacitors C1 to C3 and the reactors L1 to L3 constitute a low pass filter which is configured to allow an AC current of a commercial frequency to flow from the commercial AC power supply 5 to the converter 1 and prevent a signal of a switching frequency from flowing from the converter 1 to the commercial AC power supply 5.

The instantaneous value of the three-phase AC voltage (AC input voltage) from the commercial AC power supply 5 is detected by the controller 4. A current detector (not shown) detects an AC current (AC input current) flowing through the reactors L 1 to L3, and sends a signal indicating a detected value to the controller 4.

The positive output node of the converter 1 is connected to the positive input node of the inverter 2 via the DC line PL, and the negative output node of the converter 1 is connected to the negative input node of the inverter 2 via the DC line NL.

A battery 7 (power storage device) is connected between the DC lines PL and NL. The battery 7 is configured to store the DC power. A capacitor may be used to replace the battery 7. The DC voltage between the DC lines PL and NL is detected by the controller 4.

When the three-phase AC power is normally supplied from the commercial AC power supply 5, the converter 1 is controlled by the controller 4 to convert the three-phase AC power from the commercial AC power supply 5 into the DC power. The DC power generated by the converter 1 is supplied to the inverter 2 via the DC lines PL and NL and stored in the battery 7 as well.

At this time, the converter 1 outputs a current such that the DC voltage between the DC lines PL and NL becomes equal to a predetermined reference DC voltage. Thus, the DC voltage is kept constant. At the time of a power failure where the supply of the three-phase AC power from the commercial AC power supply 5 is stopped, the operation of the converter 1 is stopped.

When the three-phase AC power is normally supplied from the commercial AC power supply 5, the inverter 2 is controlled by the controller 4 to convert the DC power from the converter 1 into the three-phase AC power of commercial frequency. Moreover, at the time of a power failure where the supply of the three-phase AC power from the commercial AC power supply 5 is stopped, the inverter 2 converts the DC power of the battery 7 into the three-phase AC power of commercial frequency.

The three output nodes of the inverter 2 are respectively connected to one terminals of the reactors L4 to L6. The other terminals of the reactors L4 to L6 are respectively connected to one terminals of switches S1 to S3, and the other terminals of the switches S1 to S3 are respectively connected to the AC output terminals 6a to 6c. One electrodes of the capacitors C4 to C6 are respectively connected to the other terminals of the reactors L4 to L6, and the other electrodes of the capacitors C4 to C6 are collectively connected to a node NP.

The capacitors C4 to C6 and the reactors L4 to L6 constitute a low pass filter which is configured to allow an AC current of a commercial frequency to flow from the inverter 2 to the load 6 and prevent a signal of a switching frequency from flowing from the inverter 2 to the load 6. In other words, the capacitors C4 to C6 and the reactors L4 to L6 convert a three-phase rectangular wave voltage outputted from the inverter 2 into a three-phase sine wave AC voltage (AC output voltage).

The instantaneous value of the AC output voltage is detected by the controller 4. A current detector (not shown) detects an AC current (AC output current) flowing through the reactors L4 to L6, and sends a signal indicating a detected value to the controller 4.

One terminals of switches S4 to S6 are respectively connected to the AC input terminals 5a to 5c, and the other terminals thereof are respectively connected to the AC output terminals 6a to 6c. The switches S1 to S6 are controlled by the controller 4.

In the inverter power supply mode in which the three-phase AC power generated by the inverter 2 is supplied to the load 6, the switches S1 to S3 are turned on and the switches S4 to S6 are turned off. In the bypass power supply mode in which the three-phase AC power from the commercial AC power supply 5 is supplied to the load 6, the switches S1 to S3 are turned off and the switches S4 to S6 are turned on.

The controller 4 controls the uninterruptible power supply system 100 based on the AC input voltage, the AC input current, the DC voltage, the AC output current, the AC output voltage or the like. In other words, the controller 4 detects whether or not a power failure has occurred based on a detected value of the AC input voltage.

When the three-phase AC power is normally supplied from the commercial AC power supply 5, the controller 4 selects the inverter power supply mode so as to turn on the switches S1 to S3 and turn off the switches S4 to S6. Thereby, the DC power generated by the converter 1 is converted into three-phase AC power by the inverter 2, and the three-phase AC power is supplied to the load 6 via the switches S1 to S3.

The controller 4 stops the operation of the converter 1 at the time of a power failure where the supply of the three-phase AC power from the commercial AC power supply 5 is stopped. Thereby, the DC power of the battery 7 is converted into three-phase AC power by the inverter 2, and the three-phase AC power is supplied to the load 6 via the switches S1 to S3. Further, when the voltage across the terminals of the battery 7 drops to a final discharge voltage, the controller 4 stops the operation of the inverter 2, and turns off the switches S1 to S3.

When the commercial AC power supply 5 is working normally but the inverter 2 is failed, the controller 4 selects the bypass power supply mode so as to turn off the switches S1 to S3 and turn on the switches S4 to S6. Thereby, the three-phase AC power is supplied from the commercial AC power supply 5 to the load 6.

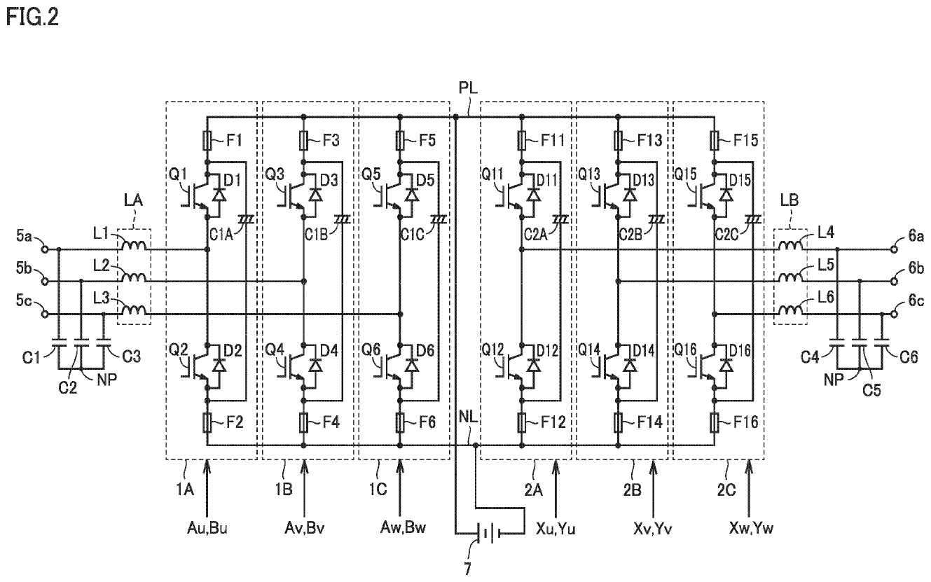

FIG. 2 is a circuit diagram illustrating the configuration of the converter 1 and the inverter 2 illustrated in FIG. 1. In FIG. 2, the switches S1 to S6 and the controller 4 are not shown.

With reference to FIG. 2, the converter 1 includes IGBTs (Insulated Gate Bipolar Transistors) Q1 to Q6, diodes D1 to D6, capacitors C1A to C1C, and fuses F1 to F6. In FIG. 2, an IGBT is used as a power semiconductor switching element (hereinafter, simply referred to as “switching element”), it should be noted that any self arc-extinguishing switching element such as MOSFET (Metal Oxide Semiconductor Field Effect Transistor) may be used as the power semiconductor switching element.

The collectors of the IGBTs Q1 to Q3 are collectively connected to the DC line PL, and the emitters thereof are respectively connected to the other terminals of the reactors L1 to L3. The collectors of the IGBTs Q4 to Q6 are respectively connected to the other terminals of the reactors L1 to L3, and the emitters thereof are collectively connected to the DC line NL.

Each of the diodes D1 to D6 is configured to allow a freewheel current to flow through when the corresponding switching element is turned off. When the switching element is a MOSFET, the freewheel diode may be a parasitic diode (body diode). When the switching element is an IGBT without a diode, the freewheel diode may be a diode connected in reversely parallel to the IGBT.

The fuses F1, F3 and F5 are connected between the collectors of the IGBTs Q1, Q3 and Q5 and the DC line PL, respectively. The fuses F2, F4 and F6 are connected between the emitters of the IGBTs Q2, Q4 and Q6 and the DC line NL, respectively.

The capacitor C1A is connected between the collector of the IGBT Q1 and the emitter of the IGBT Q2. The capacitor C1B is connected between the collector of the IGBT Q3 and the emitter of the IGBT Q4. The capacitor C1C is connected between the collector of the IGBT Q5 and the emitter of the IGBT Q6. Each of the capacitors C1A to C1C is configured to smooth a DC voltage inputted between the DC lines PL and NL.

The IGBTs Q1 and Q4 are respectively controlled by gate signals Au and Bu, the IGBTs Q2 and Q5 are respectively controlled by gate signals Av and By, and the IGBTs Q3 and Q6 are respectively controlled by gate signals Aw and Bw. The gate signals Bu, By and Bw are inverted signals of the gate signals Au, Av and Aw, respectively. Each of the gate signals Au, Bu, Av, By, Aw and Bw is a pulse signal sequence, and is a PWM (Pulse Width Modulation) signal. The phase of the gate signals Au and Bu, the phase of the gate signals Av and By and the phase of the gate signals Aw and Bw are shifted relative to each other by 120 degrees. The gate signals Au, Bu, Av, By, Aw and Bw are generated by the controller 4. By turning on or off each of the IGBTs Q1 to Q6 at a predetermined timing based on the gate signals Au, Bu, Av, By, Aw and Bw and adjusting the on time of each of the IGBTs Q1 to Q6, it is possible to convert the three-phase AC voltage supplied to the AC input terminals 5a to 5c into a DC voltage.

The inverter 2 includes IGBTs Q11 to Q16, diodes D11 to D16, capacitors C2A to C2C, and fuses F11 to F16. The collectors of the IGBTs Q11, Q13 and Q15 are collectively connected to the DC line PL, and the emitters thereof are respectively connected to one terminals of the reactors L4 to L6. The collectors of the IGBTs Q12, Q14 and Q16 are respectively connected to one terminals of the reactors L4 to L6, and the emitters thereof are collectively connected to the DC line NL. Each of the diodes D11 to D16 is configured to allow a freewheel current to flow through when the corresponding switching element is turned off.

The IGBTs Q11 and Q12 are respectively controlled by gate signals Xu and Yu, the IGBTs Q13 and Q14 are respectively controlled by gate signals Xv and Yv, and the IGBTs Q15 and Q16 are respectively controlled by gate signals Xw and Yw. The gate signals Yu, Yv and Yw are inverted signals of the gate signals Xu, Xv and Xw, respectively. Each of the gate signals Xu, Yu, Xv, Yv, Xw and Yw is a pulse signal sequence, and is a PWM signal. The phase of the gate signals Xu and Yu, the phase of the gate signals Xv and Yv and the phase of the gate signals Xw and Yw are shifted relative to each other by 120 degrees. The gate signals Xu, Yu, Xv, Yv, Xw and Yw are generated by the controller 4. By turning on or off each of the IGBTs Q11 to Q16 at a predetermined timing based on the gate signals Xu, Yu, Xv, Yv, Xw and Yw and adjusting the on time of each of the IGBTs Q11 to Q16, it is possible to convert the DC voltage between the DC lines PL and NL into a three-phase AC voltage.

In the configuration illustrated in FIG. 2, the IGBTs Q1 and Q2, the diodes D1 and D2, the fuses F1 and F2, and the capacitor C1A constitute a semiconductor unit 1A. The IGBTs Q3 and Q4, the diodes D3 and D4, the fuses F3 and F4, and the capacitor C1B constitute a semiconductor unit 1B. The IGBTs Q5 and Q6, the diodes D5 and D6, the fuses F5 and F6, and the capacitor C1C constitute a semiconductor unit 1C.

The IGBTs Q11 and Q12, the diodes D11 and D12, the fuses F11 and F12, and the capacitor C2A constitute a semiconductor unit 2A. The IGBTs Q13 and Q14, the diodes D13 and D14, the fuses F13 and F14, and the capacitor C2B constitute a semiconductor unit 2B. The IGBTs Q15 and Q16, the diodes D15 and D16, the fuses F15 and F16, and the capacitor C2C constitute a semiconductor unit 2C.

Each of the semiconductor units 1A to 1C and 2A to 2C is implemented as two switching elements which are installed on a planar substrate and each of which includes an IGBT and a diode. The IGBT and the diode are electrically connected by a wiring layer made of a bonding wire or a conductor. The IGBT and the diode are sealed by resin together with the substrate and the wiring layer. The capacitor is disposed adjacent to the substrate.

During the operation of each of the semiconductor units 1A to 1C and 2A to 2C, power loss may occur in the switching element. The power loss includes conduction loss and switching loss. The switching element generates heat due to the power loss.

As illustrated in FIG. 1, the uninterruptible power supply system 100 includes a cooling fan 8 configured to cool the semiconductor units 1A to 1C and 2A to 2C. The cooling fan 8 is driven by the three-phase AC power supplied from the inverter 2. The cooling fan 8 cools the semiconductor units 1A to 1C and 2A to 2C by forced air cooling.

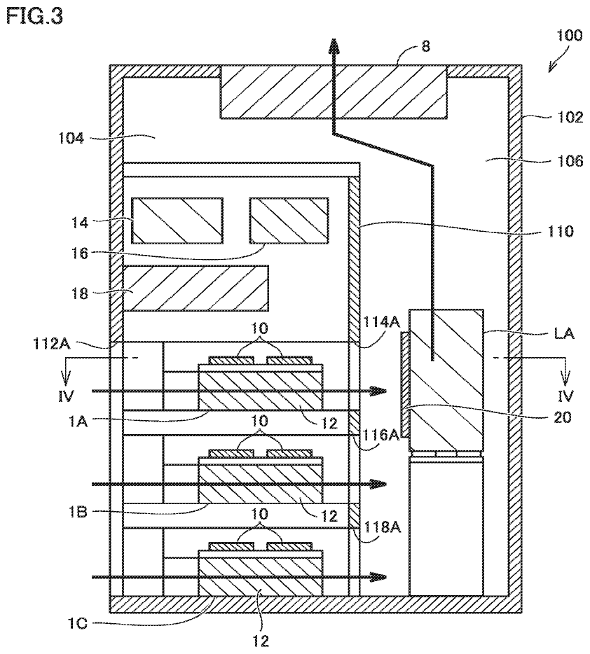

Next, the configuration of the uninterruptible power supply system 100 will be described with reference to FIG. 3.

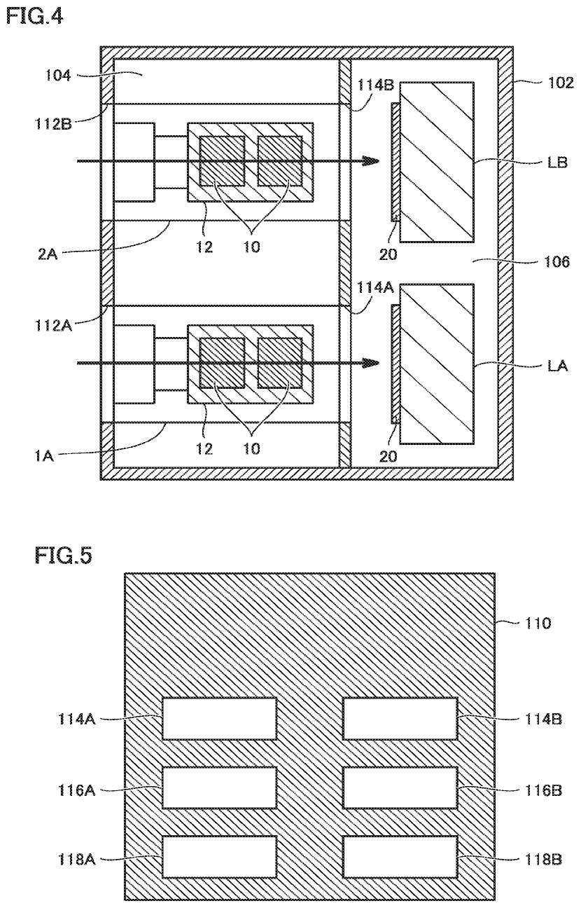

FIG. 3 is a side cross-sectional view of the uninterruptible power supply system 100. FIG. 4 is a cross-sectional view taken along line IV-IV of FIG. 3.

As illustrated in FIG. 3, the uninterruptible power supply system 100 includes a box-shaped (cube-shaped) housing 102 that houses various components therein. Specifically, semiconductor units 1 A to 1C and 2A to 2C, a capacitor unit 18, a breaker unit 16, a control unit 14, and reactor units LA and LB are installed in the housing 102. In addition to the units described above, the other elements and devices that are included in the electric circuit illustrated in FIG. 1 may be installed inside the housing 102, but they are not illustrated in the drawings for the purpose of clarity.

The inner space of the housing 102 is divided into a space 104 in which most of the components are installed and a space 106 which serves as a wind tunnel for the cooling air to flow through. The space 104 is disposed at the front side (the left side in the drawing) of the uninterruptible power supply system 100, and the space 106 is disposed at the back side (the right side in the drawing). The cooling fan 8 is provided on the top surface (the ceiling face) of the housing 102. The space 104 and the space 106 are partitioned by a partition plate 110. The front surface of the housing 102 corresponds to a “first surface” according to an embodiment, and the top surface of the housing 102 corresponds to a “second surface” according to an embodiment. The space 104 corresponds to a “first space” according to an embodiment, and the space 106 corresponds to a “second space” according to an embodiment.

The semiconductor units 1 A to 1C and 2A to 2C all have substantially the same shape. In the example of FIG. 3, each semiconductor unit has a cube shape. The semiconductor units 1A to 1C and 2A to 2C are disposed at a lower portion of the space 104. Although not illustrated in FIG. 3, the semiconductor units 2A to 2C are disposed adjacent to the semiconductor units 1A to 1C, respectively, in the horizontal direction (i.e., the depth direction in the drawing).

The switching element 10 in each semiconductor unit has a thin plate shape. The switching element 10 is disposed on cooling fins 12. The cooling fins 12 are installed on the back surface of each semiconductor unit. Each semiconductor unit is configured to allow the cooling air to flow through from the front surface to the back surface. The arrows in the figure indicate the flow of the cooling air. The cooling air cools the cooling fins 12, and thus cools the switching element 10.

The front surface of each semiconductor unit is close to the front surface of the housing 102, and the back surface of each semiconductor unit is close to the partition plate 110. The semiconductor units 1A to 1C are arranged in the vertical direction, and a gap is maintained between the semiconductor units. In the example of FIG. 3, the semiconductor unit 1C is disposed on the bottom surface of the housing 102, the semiconductor unit 1B is disposed above the semiconductor unit 1C, and the semiconductor unit 1A is disposed above the semiconductor unit 1B.

The capacitor unit 18 is configured to house the capacitors C1 to C6 illustrated in FIG. 1. The control unit 14 is implemented by a substrate or the like constituting the controller 4 illustrated in FIG. 1. The breaker unit 16 is configured to house the switches S1 to S6 illustrated in FIG. 1. The capacitor unit 18, the breaker unit 16 and the control unit 14 are disposed above the semiconductor unit 1A in the space 104.

The housing 102 is formed with air inlets 112A and 112B for the cooling air to flow through. The air inlet 112A is formed at a lower part of the front surface of the housing 102 at a position where the semiconductor units 1A to 1C are located. The air inlet 112B is formed at a lower part of the front surface of the housing 102 at a position where the semiconductor units 2A to 2C are located.

The partition plate 110 is formed with six openings 114A, 116A, 118A, 114B, 116B and 118B. FIG. 5 is an outline view of the partition plate 110. Each opening is provided at a position corresponding to the back surface of each semiconductor unit. In the example of FIG. 3, the opening 114A is provided at a position corresponding to the back surface of the semiconductor unit 1A, the opening 116A is provided at a position corresponding to the back surface of the semiconductor unit 1B, and the opening 118A is provided at a position corresponding to the back surface of the semiconductor unit 1C. Although not illustrated in FIG. 3, the opening 114B is provided at a position corresponding to the back surface of the semiconductor unit 2A, the opening 116B is provided at a position corresponding to the back surface of the semiconductor unit 2B, and the opening 118B is provided at a position corresponding to the back surface of the semiconductor unit 2C.

As illustrated by the arrows in FIGS. 3 and 4, the cooling air sucked from the air inlet 112A flows through the cooling fins 12 of each of the semiconductor units 1A to 1C so as to cool the same, and is then discharged into the space 106 through the openings 114A, 116A and 118A of the partition plate 110. The cooling air discharged into the space 106 flows upward, and is discharged to the outside of the housing 102 by the cooling fan 8.

The reactor unit LA is configured to house the reactors L1 to L3 illustrated in FIG. 1, and the reactor unit LB is configured to house the reactors L4 to L6 illustrated in FIG. 1. Each of the reactors L1 to L6 includes a coil and a terminal provided at the end of a lead extended from the coil.

Each of the reactor units LA and LB has, for example, a cuboid shape or a cylindrical shape. The reactor units LA and LB are disposed inside the space 106. In other words, the reactor units LA and LB are disposed in a wind tunnel of the cooling air which has cooled the semiconductor units 1A to 1C and 2A to 2C.

Specifically, as illustrated in FIG. 4, the reactor unit LA is disposed to face at least one of the openings 114A, 116A and 118A of the partition plate 110, and the reactor unit LB is disposed to face at least one of the openings 114B, 116B and 118B of the partition plate 110. In the example of FIG. 3, the reactor unit LA is disposed to face the opening 114A, and the reactor unit LB is disposed to face the opening 114B.

With such a configuration, the cooling air discharged from the opening 114A may directly hit against the reactor unit LA. Similarly, the cooling air discharged from the opening 114B may directly hit against the reactor unit LB.

In the thermal design of a reactor, in order to reduce the calorific value of the reactor per unit volume, it is often to reduce the current density of the reactor by using a wire with a larger diameter. Further, in order to increase the heat dissipation area, it is often to increase the number of turns of the reactor. However, these measures may lead to an increase in the size and weight of the reactor as well as an increase in the cost. In order to reduce the size, weight and cost of the reactor, it is required to improve the heat dissipation of the reactor.

In the present embodiment, the heat radiation of the reactor may be improved by allowing the cooling air to directly hit against the reactor units LA and LB. As a result, it is possible to prevent the size, weight and cost of the reactor from increasing.

In the example of FIG. 3 and FIG. 4, the reactor units LA and LB are disposed such that a terminal member 20 of each reactor unit faces a respective one of the openings 116A and 116B. The terminal member 20 is constituted by a terminal provided at the end of a lead extended from the coil of the reactor housed in each reactor unit, and protrudes outward from the reactor unit. Therefore, the heat generated by the reactor may be radiated from the terminal member 20 to the outside. In other words, the terminal member 20 may function as a heat dissipation member of the reactor. The heat dissipation of the reactor may be improved by allowing the cooling air to directly hit against the terminal member 20.

As described above, according to the semiconductor device of the present embodiment, the heat radiation of the reactor may be improved by allowing the cooling air to directly hit against the reactor unit after flowing through the semiconductor unit. Thereby, it is possible to simplify the thermal design of the reactor, which makes it possible to reduce the size, weight and cost of the reactor.

<First Modification>

In the embodiment described above, it is described that the reactor unit LA is disposed to face at least one of the three openings 114A, 116A and 118A.

However, if the wind speed of the cooling air discharged from each of the openings 114A, 116A and 118A is different, the reactor unit may be disposed to face the opening through which the cooling air has the fastest wind speed.

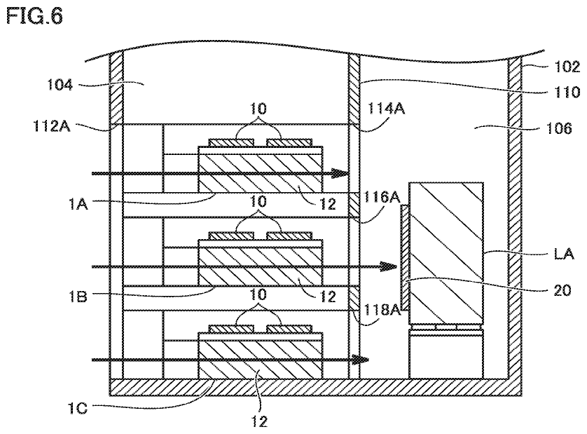

FIG. 6 is a side cross-sectional view of an uninterruptible power supply system 100 according to a first modification of the present invention. In FIG. 6, it is assumed that among the openings 114A, 116A and 118A, the cooling air flowing through the opening 116A has the fastest wind speed. Thus, the reactor unit LA is disposed to face the opening 116A.

As illustrated in FIG. 6, when the cooling air is different in wind speed, in order to sufficiently cool all of the semiconductor units 1 A to 1C, the cooling fan 8 is used so as to sufficiently cool the semiconductor unit with the slowest wind speed. However, with regard to the semiconductor unit 1B with the fastest wind speed, the wind speed of the cooling wind would be faster than necessary. In other words, extra energy is consumed by the cooling fan 8.

In the example of FIG. 6, a minimum energy may be used to cool the reactor by allowing the cooling air with the fastest wind speed to hit against the reactor unit LA. Thus, the semiconductor unit and the reactor may be cooled efficiently, preventing the energy for cooling the reactor from being wasted.

<Second Modification>

In the embodiment described above, it is described that the cooling air is configured to hit against the terminal member 20 of each of the reactor units LA and LB. However, depending on the layout inside the housing 102 and the shape of the reactor units, it may be difficult to arrange a reactor unit so that the terminal member 20 faces an opening of the partition plate 110. In such a case, a heat dissipation plate (heat sink) may be attached to each of the reactor units LA and LB, and the cooling air may be configured to hit against the heat dissipation plate.

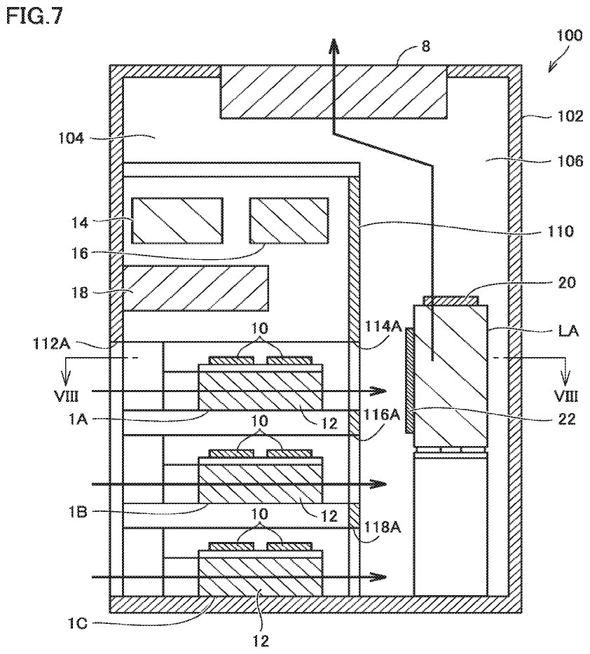

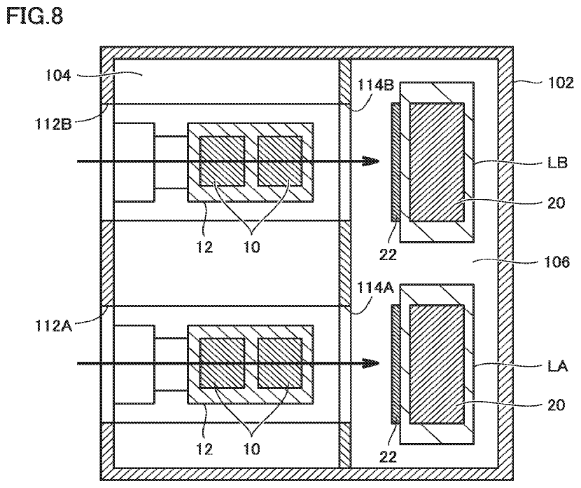

FIG. 7 is a side cross-sectional view of an uninterruptible power supply system 100 according to a second modification of the present invention. FIG. 8 is a cross-sectional view taken along line VIII-VIII of FIG. 7.

With reference to FIG. 7, a heat dissipation plate 22 is attached to the side surface of the reactor unit LA that faces the opening. The heat dissipation plate 22 may be planar and have a rectangular shape, for example. The heat dissipation plate 22 may be provided with cooling fins. The heat dissipation plate 22 may be thermally connected to the reactor unit LA. The heat generated from the reactor is radiated to the outside of the reactor unit LA through the heat dissipation plate 22.

The reactor units LA and LB are disposed such that the heat dissipation plate 22 faces the opening. In the example of FIGS. 7 and 8, the reactor unit LA is disposed such that the heat dissipation plate 22 faces the opening 114A, and the reactor unit LB is disposed such that the heat dissipation plate 22 faces the opening 114B. Since the cooling air may directly hit against the heat dissipation plate 22, the heat dissipation of the reactor may be improved.

In addition, although not illustrated in the drawings, the heat dissipation plate 22 may be disposed adjacent to the terminal member 20 of the reactor unit, and thereby, the cooling air may directly hit against both the heat dissipation plate 22 and the terminal member 20, which makes it possible to further improve the heat dissipation of the reactor.

In the present disclosure, it is described that the reactor unit with reactors housed therein is cooled by the cooling air, but in the case where the uninterruptible power supply system includes a transformer, the invention described in the embodiments and the modifications may be applied to the transformer so as to improve the heat dissipation of the transformer.

Further, in the present disclosure, the cooling of the reactor units LA and LB has been mainly described, but the invention described in the embodiment may be applied to other components such as the control unit, the capacitor unit or the breaker unit so as to improve the heat dissipation thereof.

Furthermore, in the present disclosure, it is described that semiconductor units are stacked in three stages, the semiconductor units are not limited to be stacked in multiple stages. Also, the openings may be provided in any number. By arranging the reactor unit so as to face an opening provided in corresponding relation to the semiconductor unit, it is possible to improve the heat dissipation of the reactor.

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### REFERENCE SIGNS LIST

1: converter; 2: inverter; 4: controller; 5: commercial AC power supply; 5a to 5c: AC input terminal; 6: load; 6a to 6c: AC output terminal; 7: battery; 8: cooling fan; 10: switching element; 12: cooling fins; 14: control unit; 16: breaker unit; 18: capacitor unit; 20: terminal member; 22: heat dissipation plate; 100: uninterruptible power supply system; 102: housing; 104, 106: space; 110: partition plate; 112A, 112B: air inlet; 114A, 114B, 116A, 116B, 118A, 118B: opening; C1 to C6, C1A to C1C, C2A to C2C: capacitor; L1 to L6: reactor; LA, LB: reactor unit; Q1 to Q6, Q11 to Q16: IGBT; D1 to D6: diode; F1 to F6, F11 to F16: fuse; S1 to S6: switch

1. A semiconductor device comprising:
a box-shaped housing having a first surface which is formed with an air inlet and a second surface which is different from the first surface;
a cooling fan provided on the second surface, the cooling fan discharging air from the second surface; and
a partition plate that partitions a space inside the box-shaped housing into a first space in contact with the first surface and a second space in contact with the second surface;
the partition plate being formed with openings so as to allow the cooling air generated by the cooling fan to flow through the first space into the second space,
the semiconductor device further comprising:
at least one semiconductor unit disposed in the first space and cooled by the cooling air; and
a reactor unit disposed in the second space, the reactor unit housing a reactor;
among the openings, the reactor unit is disposed to face a first opening through which the cooling air has the fastest wind speed.

2. (canceled)

3. The semiconductor device according to claim 1, wherein
the reactor unit is provided with a terminal member that includes therein a terminal of the reactor, and the reactor unit is disposed such that the terminal member faces the first opening.

4. The semiconductor device according to claim 1, further includes a heat dissipation plate that is thermally connected to the reactor unit, and
the reactor unit is disposed such that the heat dissipation plate faces the first opening.

5. The semiconductor device according to claim 1, wherein
the at least one semiconductor unit includes semiconductor units,
the openings in the partition plate are formed in corresponding relation to the semiconductor units, and
the reactor unit is disposed to face the first opening.
